(19) United States
(12) Patent Application Publication
(10) Pub. No.: US 2023/0060494 A1
(43) Pub. Date: Mar. 2, 2023

(54) APPARATUS FOR ADAPTING REPLICA WEAPONS TO A VIRTUAL REALITY SYSTEM

(71) Applicant: Street Smarts VR, New York, NY (US)

(72) Inventor: Greg Prodzenko, Philadelphia, PA (US)

(21) Appl. No.: 17/412,818

(22) Filed: Aug. 26, 2021

(51) Int. Cl. F41A 33/00; H01H 21/22; H05K 7/14

(52) U.S. Cl. CPC F41A 33/00; H01H 21/22; H05K 7/14

(57) ABSTRACT

A selective fire detection assembly for detecting selective fire of a selective-fire weapon coupled to a virtual reality system, the selective fire detection assembly comprising a circuit board comprising a safety detection switch comprising a first electrical circuit configured to communicate signals representative of firing modes selected on a selective-fire weapon to a virtual reality computing device. The circuit board further comprising a trigger detection switch comprising a second electrical circuit configured to communicate signals representative of trigger pull on the selective-fire weapon to the virtual reality computing device. The circuit board further comprising a mounting bracket configured to mount the circuit board to the selective-fire weapon.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### CROSS REFERENCE TO RELATED APPLICATION

This application is related to the following patents and applications, which are assigned to the assignee of the present invention:
U.S. Pat. Application No. 16/930,050, entitled “MAGAZINE SIMULATOR FOR USAGE WITH WEAPONS IN A VIRTUAL REALITY SYSTEM,” filed on Jul. 15, 2020, and
U.S. Pat. Application No. 16/930,060, entitled “A VIRTUAL REALITY SYSTEM FOR USAGE WITH SIMULATION DEVICES,” filed on Jul. 15, 2020.
The above identified patents and applications are incorporated by reference herein in their entirety.

### BACKGROUND OF THE INVENTION

### Field of the Invention

This application generally relates to detecting selective fire, and in particular, a selective fire detection assembly for a selective fire weapon coupled to a virtual reality system.

### Description of the Related Art

It has long been desired to provide personnel training to improve their skills in aiming and firing shotguns, rifles, handguns, and other weapons. Law enforcement and military training often place trainees into situations that require quick visual and mental assessment of the situation as well as an appropriate response with a weapon. Trainees are often subjected to adverse situations to test their abilities to effectively react.

Traditional training methods in marksmanship and firing tactics for hunters and other sportsmen, police, military personnel, and others, leave much to be desired from the aspects of realism, cost and practicality. Many firing ranges have limited capacity. Moreover, most existing firing ranges do not provide protection for the shooter against the natural elements such as rain or snow. Because of the noise levels normally associated with firing ranges, they are typically located in remote areas requiring people to have to drive to remote locations. The ammunition, targets and use costs for the range, make such training expensive. Furthermore, when live ammunition is used, expense, risks, administrative problems, safety concerns, and government rules and regulations are more burdensome. For training in marksmanship and tactics, it is beneficial to have an indoor range where shooters can fire simulated projectiles against simulated moving targets.

Video games are increasingly more realistic where users may be placed into immersive virtual environments. First-person-view shooting games offer players the ability to perform actions such as walking, crouching, shooting, etc., using a mouse and keyboard. However, these games are usually played in front of a computer where the user is sitting in a chair and are adequate for personnel training. Virtual reality systems may improve gaming experience where the player’s movement in the game is dependent on their actions in physical space which makes the game more immersive than a traditional video game. Despite the realism provided by virtual reality systems, players are often provided with game controllers that are either tethered or have the look and feel of toys. As such, existing virtual reality game controllers that are representative guns differ from actual guns in feel and balance, and thus reduces the effectiveness of the training for real life.

There is thus a need to provide improved hardware for virtual reality shooting simulators.

### SUMMARY OF THE INVENTION

The present invention provides a selective fire detection assembly for detecting selective fire of a selective fire weapon coupled to a virtual reality system. According to one embodiment, the selective fire detection assembly comprises a circuit board and a mounting bracket configured to mount the circuit board to the selective-fire weapon. The circuit board comprises a safety detection switch comprising a first electrical circuit configured to communicate signals representative of firing modes selected on a selective-fire weapon to a virtual reality computing device. The circuit board further comprises a trigger detection switch comprising a second electrical circuit configured to communicate signals representative of trigger pull on the selective-fire weapon to the virtual reality computing device.

The firing modes may include at least one of safe, semi-automatic, burst, and fully automatic. The switch lever interface may comprise a mechanical structure adapted to the safety selector lever. The firing mode signals and the trigger pull signals may be communicated to the virtual reality computing device via a wireless or wired connection. According to one embodiment, the selective-fire weapon comprises a M4 Carbine. In one embodiment, the mounting bracket may be configured to mount the circuit board within a cavity of the selective-fire weapon. In another embodiment, the mounting bracket may be configured to mount the circuit board to a lower receiver of the selective-fire weapon. The trigger detection switch button may be toggled by trigger pull movement of a trigger mechanism of the selective-fire weapon.

The safety detection switch button can be toggled via the switch lever interface by rotating a face of the safety selector lever. The safety selector switch may comprise a rotating mechanism including a plurality of positions corresponding to the firing modes. The safety selector switch may include a channel having a notched portion and a cutout portion, wherein the notched portion and the cutout portion corresponding to positions associated with the firing modes. The switch lever interface may be configured within the channel. The safety selector switch can be rotated to toggle between the firing modes by causing the switch lever interface to travel between the notched portion and the cutout portion. The safety detection switch may include a safety detection switch button that toggles the safety detection switch and a switch lever interface that interfaces the safety detection switch button with a safety selector lever. The trigger detection switch may include a trigger detection switch button that toggles the trigger detection switch by trigger pull movement of the selective-fire weapon.

### BRIEF DESCRIPTION OF THE DRAWINGS

The invention is illustrated in the figures of the accompanying drawings which are meant to be exemplary and not limiting, in which like references are intended to refer to like or corresponding parts.

FIG. 1 illustrates a magazine simulator according to an embodiment of the present invention.

FIG. 2 illustrates a cutaway view of a handle portion of a gun including a magazine simulator according to an embodiment of the present invention.

FIG. 3 illustrates a bottom view of a tracker interface according to an embodiment of the present invention.

FIG. 4 illustrates a cutaway view of an electronic control weapon including a magazine simulator according to an embodiment of the present invention.

FIG. 5 illustrates a bottom view of a tracker interface according to another embodiment of the present invention.

FIG. 6 illustrates a tracker according to an embodiment of the present invention.

FIG. 7 illustrates a front handle view of a handgun loaded with a magazine assembly according to an embodiment of the present invention.

FIGS. 8 and 9 illustrate repeater mechanisms according to embodiments of the present invention.

FIG. 10 illustrates a computing system according to an embodiment of the present invention.

FIG. 11 illustrates an adapter circuit for detecting selective fire according to an embodiment of the present invention.

FIG. 12 illustrates an adapter circuit installed within a cavity of a weapon according to an embodiment of the present invention.

FIGS. 13 and 14 illustrate cutaway views of an adapter circuit configured in a lower receiver according to an embodiment of the present invention.

FIG. 15 illustrates an exemplary safety selector switch according to an embodiment of the present invention.

### DETAILED DESCRIPTION OF THE INVENTION

Subject matter will now be described more fully hereinafter with reference to the accompanying drawings, which form a part hereof, and which show, by way of illustration, exemplary embodiments in which the invention may be practiced. Subject matter may, however, be embodied in a variety of different forms and, therefore, covered or claimed subject matter is intended to be construed as not being limited to any example embodiments set forth herein; example embodiments are provided merely to be illustrative. It is to be understood that other embodiments may be utilized and structural changes may be made without departing from the scope of the present invention. Likewise, a reasonably broad scope for claimed or covered subject matter is intended. Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of exemplary embodiments in whole or in part. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

The present application discloses systems, devices, and methods that employ virtual reality to train police officers or military in the use of weapons like guns or electronic control weapons (e.g., those available from Taser™) in specific scenarios or situations. A trainee may be given an actual weapon or a training weapon that simulates an actual weapon and is connected to a virtual reality system. The trainee may wear goggles or headsets that are connected to the virtual reality system which plays a training scenario. Throughout the training scenario, the trainee’s use of his weapon may be tracked and provided to the virtual reality system.

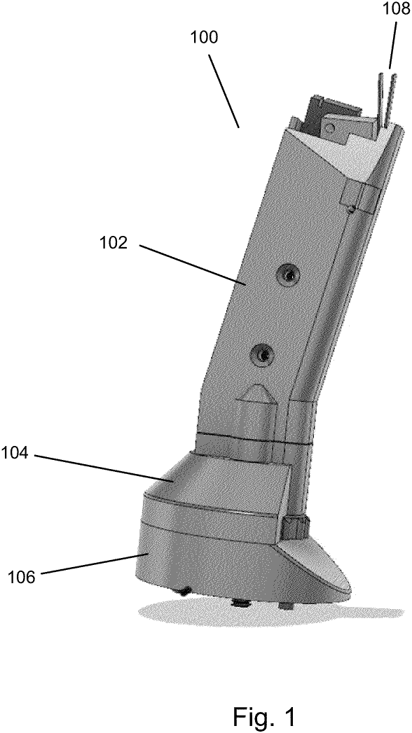

FIG. 1 illustrates a magazine simulator according to an embodiment of the present invention. Magazine simulator 100 may be provided to a real gun, such as a Glock handgun, and operates or fires (e.g., virtually) when a trigger of the gun is pulled. The magazine simulator 100 may also be used with replica weapons, such as Airsoft or toy guns. The magazine simulator may be inserted into a magazine well or a magazine inserting portion of a gun, according to an embodiment of the present invention. The magazine simulator 100 may comprise a box magazine 102, a tracker interface 104, and a tracker 106. The box magazine 102 may include a switch 108 that when inserted into a magazine well of a gun, may be articulated with a trigger or firing mechanism of the gun. Switch 108 may comprise one or more tabs, hooks or levers that are connected to electronic circuitry or sensors in box magazine 102. The switch 108 may be actuated by a gun trigger which may then connect an electrical signal from box magazine 102 to tracker interface 104. Box magazine 102 may further include weights for modifying the balance and feel of a gun when inserted. In one embodiment, force feedback may be provided by compressed gas or a weight controlled by servo motors within box magazine 102 for enhanced realism while firing (based on the articulations of the switch).

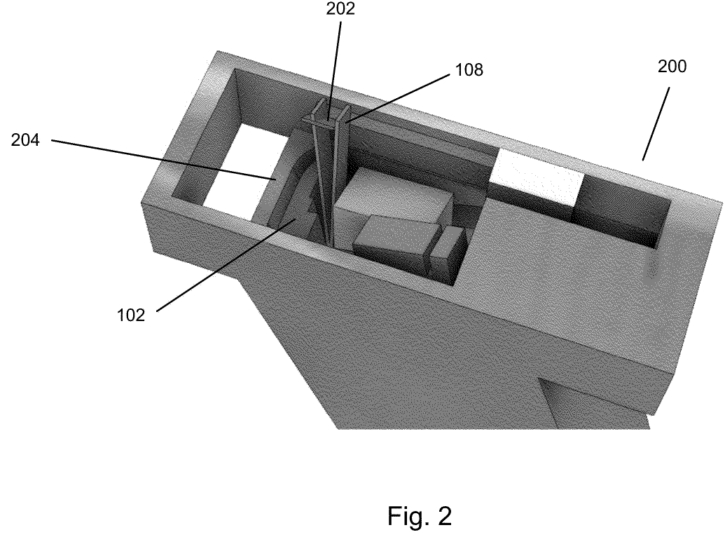

FIG. 2 presents a cutaway view of a handle portion of a gun including a magazine simulator according to an embodiment of the present invention. The box magazine 102 can be inserted into magazine well 204 of gun 200. When inserted, switch 108 may be configured with trigger connection 202. Trigger connection 202 may be connected to a trigger (not illustrated) of the gun such that when the trigger is pulled, trigger connection 202 may move and engage with switch 108 which causes switch 108 to send a signal to tracker interface 104 to indicate that the trigger has been pulled. According to one embodiment, switch 108 may be adjustably configured with a plurality of trigger pull distances. Box magazine 102 may be suitable for insertion into magazine wells of traditional guns. However, components of box magazine 102 may be modified for other types of weapons, such as an electronic control weapon, where a battery pack may be inserted into the magazine well instead of a magazine with bullets.

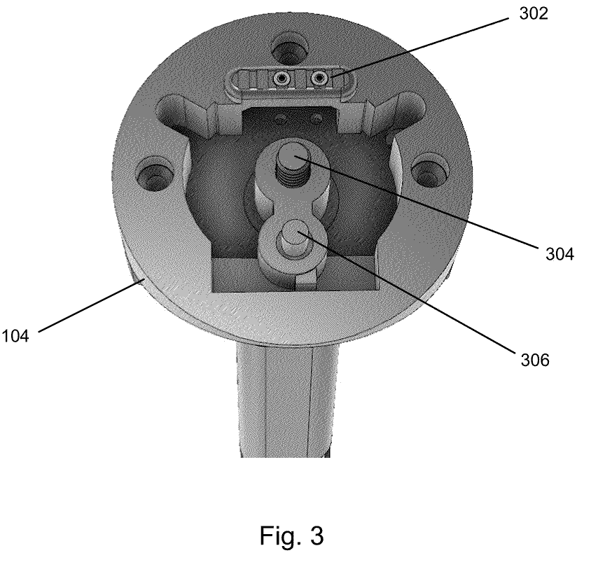

FIG. 3 presents a bottom view of a tracker interface according to an embodiment of the present invention. Box magazine 102 may be assembled or attached to tracker interface 104. Tracker interface 104 may include pin pad 302, screwing bolt 304, and stabilizing pin 306. Pin pad 302 may include pins corresponding to given signals from switch 108 of box magazine 102. In the exemplary embodiment presented in FIG. 3, pin pad 302 includes two pins. For example, a first pin may correspond to a trigger pull signal and a second pin may correspond to a ground connection.

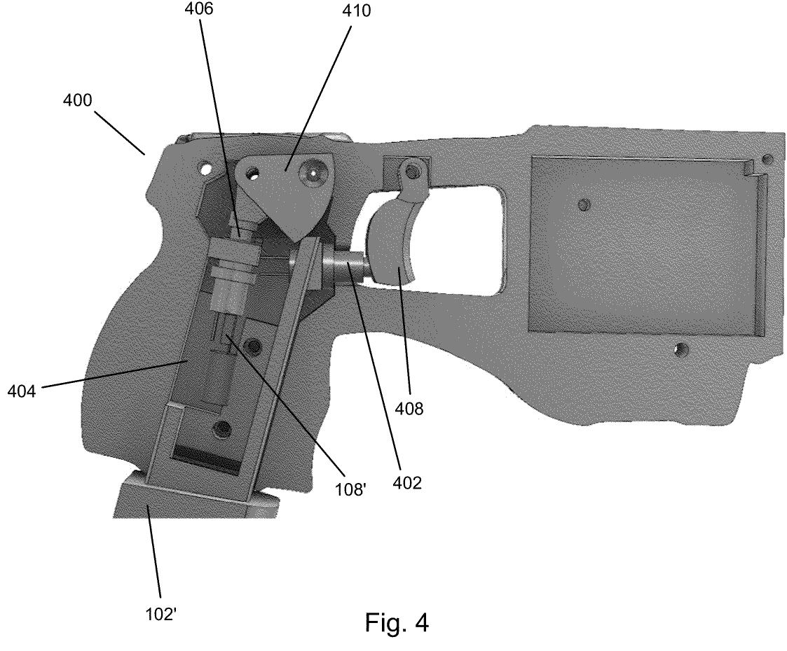

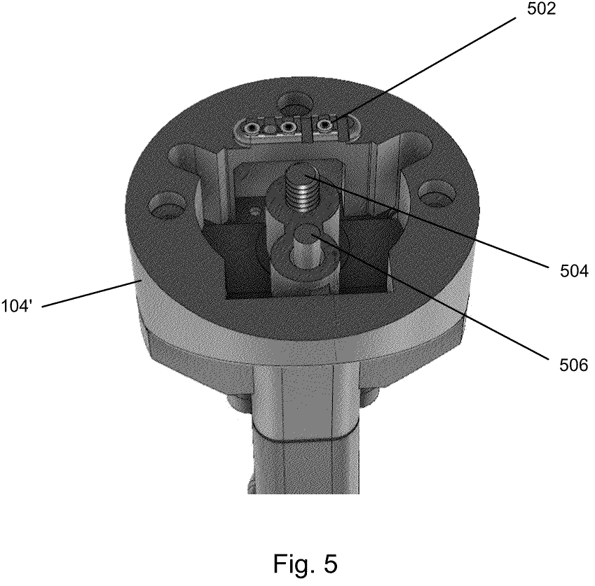

FIG. 4 presents a cutaway view of an electronic control weapon including a magazine simulator according to an embodiment of the present invention. Electronic control weapon 400 may include a magazine well 404 operable to receive a box magazine 102'. Box magazine 102' may include a switch 108' that may be actuated by trigger component 402 and a switch 110 operated by safety component 406. Safety component 406 may be correlated with on and off positions of a safety 410. Operation of the safety 410 may cause safety component 406 to transmits a signal to switch 110 that indicates the position of the safety 410 (e.g., either on or off). Trigger component 402 may be coupled to a trigger 408 of the electronic control weapon 400 such that when the trigger is pulled, trigger component 402 may communicate a signal to switch 108' that indicates the trigger 408 has been pulled. Switch 108' may relay signals from trigger component 402 and switch 110 may relay signals from safety component 406 to the tracker interface 104' illustrated in FIG. 5. Electronic control weapon 400 may further include a weight 112 that provides a weight and feel of a realistic (e.g., electronic) weapon.

FIG. 5 presents a bottom view of a tracker interface according to another embodiment of the present invention. Box magazine 102' may be assembled or attached to tracker interface 104'. Tracker interface 104' includes pin pad 502, screwing bolt 504, and stabilizing pin 506. In this exemplary embodiment, pin pad 502 includes three pins, e.g., a first pin may correspond to a trigger pull signal, a second pin may correspond to a safety position, and a third pin may correspond to a ground connection. Pin pad 502 may include pins corresponding to given signals from switches 108' and 110 of box magazine 102'.

Signals from switches 108, 108', or 110 may be transmitted to tracker interfaces 104, 104', respectively, and activate corresponding electrical switches to pin pads 302 and 502. Articulations from gun 200 or electronic control weapon 400 that are communicated to any ones of switches 108, 108', or 110 are not limited to trigger pulls and safety positions and may include other actions, events or signals that may be generated from weapons. Pin pad 302 and 502 may provide an electrical connection interface with tracker 106.

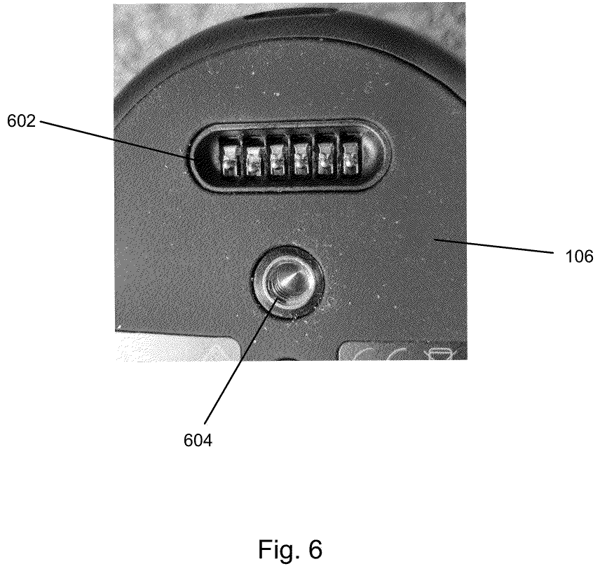

FIG. 6 presents a tracker according to an embodiment of the present invention. Tracker 106 may comprise hardware configured to track and link actions, events or signals from gun 200 or electronic control weapon 400 to a virtual reality computing device. Tracker interfaces 104, 104' may be attached to tracker 106 to facilitate communications between gun 200 or electronic control weapon 400 wirelessly to a virtual reality computing device. According to one embodiment, the virtual reality computing device may comprise a server running a Unity engine (Unity Technologies) that is interface with a tracker 106 that includes hardware, software, and software development tools from virtual reality providers such as VIVE™.

Signals from pin pads 302 and 502 on tracker interfaces 104 and 104' may be convey to tracker 106 via pogo pin connector 602. Pogo pin connector 602 may comprise a plurality of spring-loaded pins that support electrical connection with pins on pin pads 302, 502. Signals from the pins on pin pads 302, 502 may be mapped into commands based on contact connections with corresponding pins on pogo pin connector 602. The commands generated on tracker 106 may be received and interpreted by the virtual reality computing device.

Tracker interfaces 104 and 104' may be mated with tracker 106 by inserting stabilizing pin 306 and 506, respectively, into a stabilizing pin recess (not illustrated) of tracker 106. The stabilizing pins 306, 506 provide proper alignment and contact between pin pads 302, 502 and pogo pin connector 602. Tracker 106 may further include image sensors and/or nonoptical sensors (e.g., utilizing sound waves or magnetic fields) that can be installed in hardware to track the movement of a user’s body. According to another embodiment, optical markers may be placed on tracker 106 (or alternatively on magazines 102, 102', or tracker interfaces 104, 104') for motion tracking using cameras to track movement of a user.

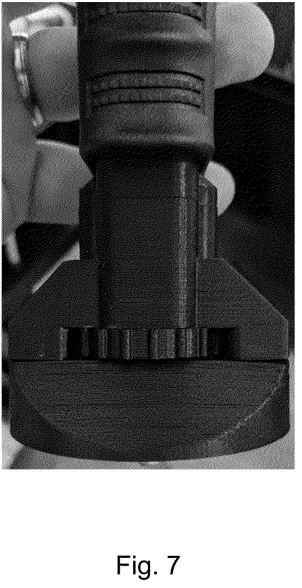

Tracker interfaces 104, 104' may be secured to tracker 106 by securing screwing bolts 304, 504 to mount 604. Screwing bolts 304, 504 may be tightened and loosened from mount 604 via a thumbwheel 114 as illustrated in FIG. 7. FIG. 7 illustrates a front handle view of a gun loaded with a magazine assembly according to an embodiment of the present invention. The thumbwheel may be tightened until the tracker interface (104, 104') is securely fixed in place with tracker 106. As such, an assembly of box magazine 102, 102', tracker interface 104, 104, and tracker 106 provides a magazine simulator 100 provides a virtual reality controller device that can be holstered and unholstered, useful in simulating real training.

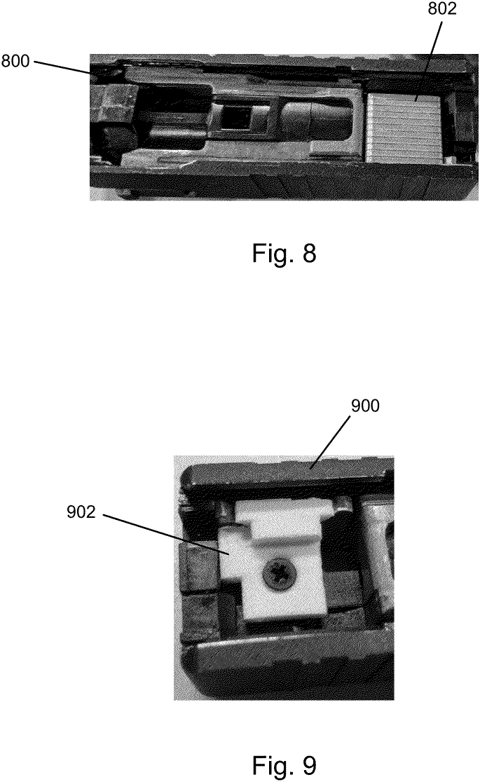

FIG. 8 presents a repeating mechanism according to an embodiment of the present invention. Certain guns may include a slide lock or release that functions to lock a slide in its “back” position when a gun has expended all ammunition from a magazine. To prohibit a gun from locking its slide, a repeater 802 may be inserted into a slide 800 of a gun. The repeater 802 may disable a slide lock or slide release to prohibit the slide 800 from locking upon firing with an empty magazine (e.g., box magazine 102, 102'). Furthermore, the repeater 802 may ensure the trigger of the gun is reset. That is, after firing, the trigger may be either held in position or goes limp/disconnected. When the slide 800 cycles due to firing, the trigger can be reset so that the gun may fire again. The repeater 802 in this case prevents the “dead trigger” so that the trigger of the gun can be pulled repeatedly without the slide 800 cycling. Similarly, FIG. 9 depicts a repeater 902 comprising a fitted piece that may be secured to slide 900.

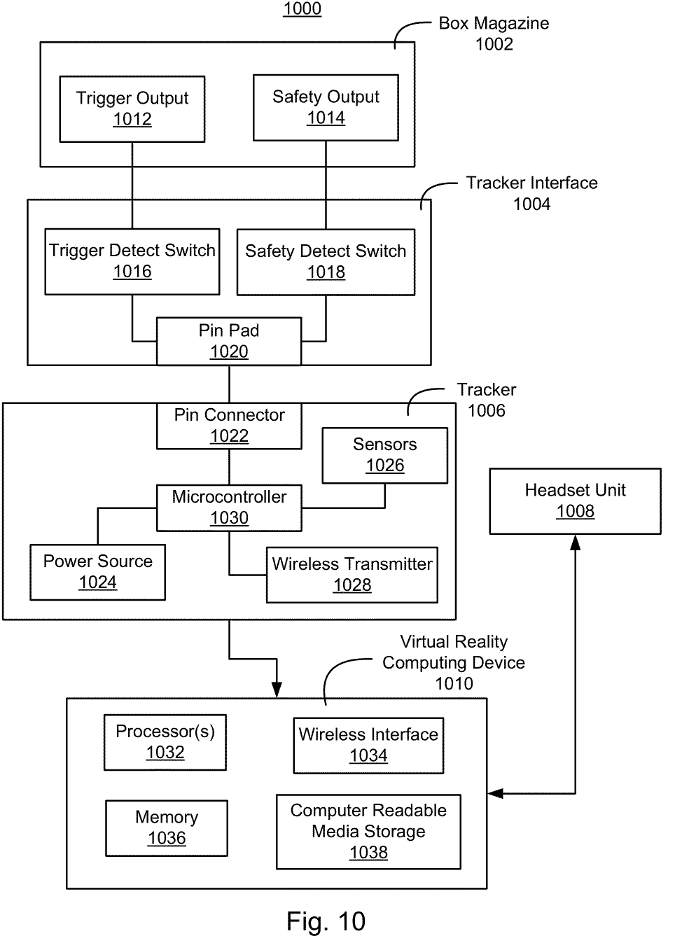

FIG. 10 presents a computing system according to an embodiment of the present invention. A system 1000 may include box magazine 1002, tracker interface 1004, tracker 1006, headset unit 1008, and virtual reality computing device 1010. Box magazine 1002 may comprise a housing insertable into a magazine well of a gun and include a trigger detect switch 1016 and safety detect switch 1018. The trigger detect switch 1016 and safety detect switch 1018 may provide electrical connections or signals to indicate a pull of a trigger or a position of a safety, respectively.

The box magazine 1002 may be coupled to tracker interface 1004. The tracker interface 1004 may include trigger output 1012 and safety output 1014. Trigger detect switch 1016 may include a circuit component that opens and closes an electrical circuit to trigger output 1012. Similarly, safety detect switch 1018 may include a circuit component that opens and closes an electrical circuit to safety output 1014. According to other embodiment, trigger detect switch 1016 and safety detect switch 1018 may be in another housing that is coupled to box magazine 1002, or tracker interface 1004, or both. The electrical connections or signals corresponding to trigger output 1012 and safety output 1014 may be carried to given pins on pin pad 1020.

Tracker interface 1004 may be further coupled to tracker 1006. Tracker 1006 includes pin connector 1022, power source 1024, sensors 1026, wireless transmitter 1028, and microcontroller 1030. Pin pad 1020 may be communicatively or electrically connected to pin connector 1022. Power source 1024 may be connected to microcontroller 1030 and used by microcontroller 1030 to provide a voltage source to components within box magazine 1002 and tracker interface 1004 via pin connector 1022. As such, microcontroller 1030 may receive signals from closed electrical circuits connected to pin connector 1022 and transmit the signals to virtual reality computing device 1010 via wireless transmitter 1028. Virtual reality computing device 1010 may process or render the signals using processor(s) 1032 and transmit corresponding images to headset unit 1008 from wireless interface 1034.

Microcontroller 1030 may also provide power to sensors 1026 and wireless transmitter 1028 from power source 1024. Sensors 1026 can detect a position of tracker 1006 within the x, y and z coordinates of a space, as well as orientation including yaw, pitch and roll. From a user’s perspective, a gun connected to tracker 1006 may be tracked when pointed up, down, left and right, tilted at an angle, or moved forward or backwards. Sensors 1026 may communicate where the gun is oriented to microcontroller 1030 which sends the data to virtual reality computing device 1010 for processing by processor(s) 1032 and renders corresponding images for transmission by wireless interface 1034 to headset unit 1008.

Headset unit 1008 may comprise a head mounted display, also including components similar to tracker 1006, that a user can place over the user’s eyes. The headset unit 1008 may be configured to communication with the virtual reality computing device 1010 to provide display according to a virtual reality simulation program. Additionally, the headset unit 1008 may be configured with positioning and/or motion sensors to provide user motion inputs to virtual reality computing device 1010. When wearing the headset unit 1008, the view may shift as the user looks up, down, left and right. The view may also change if the user tilts their head at an angle or move their head forward or backward without changing the angle of gaze. Sensors on headset unit 1008 may communicate to processor(s) 1032 where the user is looking, and the processor(s) 1032 may render corresponding images to the head mounted display. Sensors, as disclosed herein, can detect signals of any form, including electromagnetic signals, acoustic signals, optical signals and mechanical signals.

Virtual reality computing device 1010 includes processor(s) 1032, wireless interface 1034, memory 1036, and computer readable media storage 1038. Processor(s) 1032 may be configured to execute virtual reality training software stored within memory 1036 and/or computer readable media storage 1038, to communicate data to and from memory 1036, and to control operations of the virtual reality computing device 1010. The processor(s) 1032 may comprise central processing units, auxiliary processors among several processors, and graphics processing units. Memory 1036 may include any one or combination of volatile memory elements (e.g., random access memory (RAM). Computer readable media storage 1038 may comprise non-volatile memory elements (e.g., read-only memory (ROM), hard drive, etc.). Wireless interface 1034 may comprise a network device operable to connect to a wireless computer network for facilitating communications and data transfer with tracker 1006 and headset unit 1008.

The virtual reality training software may comprise an audio/visual interactive interface that enables a trainee to interact with a three-dimensional first-person-view environment in training scenarios with tracker devices, such as a weapon including a virtual reality-enabled magazine assembly (e.g., comprising box magazine 1002, tracker interface 1004, and tracker 1006). Virtual reality computing device 1010 may receive signals or commands from tracker 1006 and headset unit 1008 to generate corresponding data (including audio and video data) for depiction in the virtual reality environment.

The disclosed embodiments with reference to FIGS. 1 through 10 depict exemplary weapon devices and hardware that may be used with the disclosed system. However, the disclosed system is compatible with other weapons, magazine simulators, or interface devices.

According to another embodiment, the disclosed system may be used with selective-fire weapons. Selective-fire weapons include weapons with multiple firing modes, such as safe, semi-automatic, burst, and fully automatic, etc. Firing modes of selective-fire weapons may be selected by a selector switch. To communicate the different firing modes to the disclosed virtual reality computing device, a specialized circuit board may be adapted and fitted to selective-fire weapons.

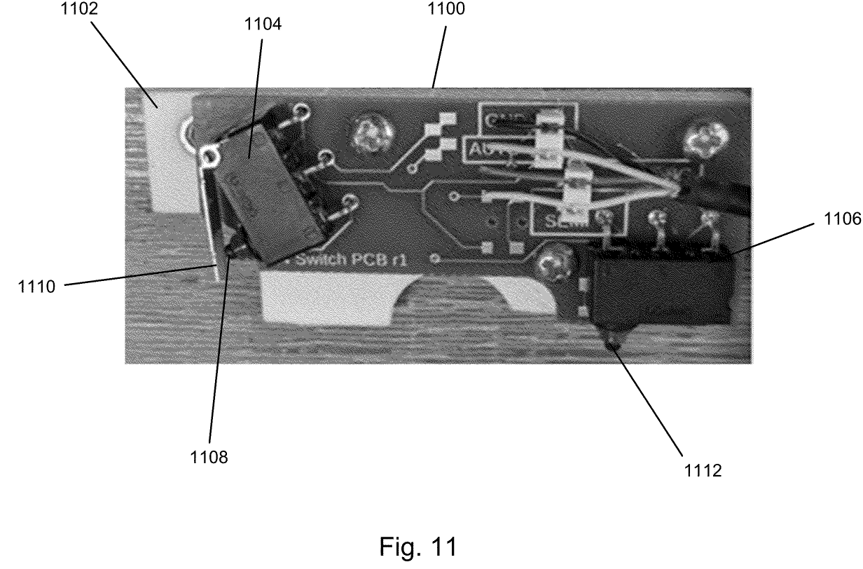

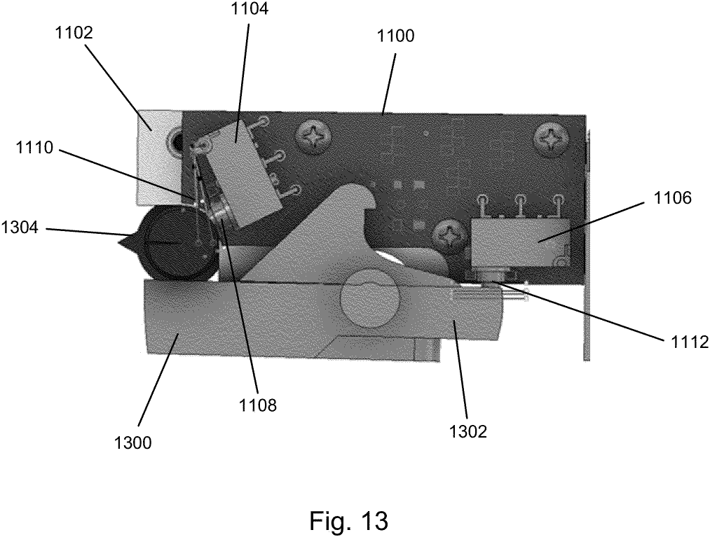

FIG. 11 presents an adapter circuit for detecting selective fire according to an embodiment of the present invention. The adapter circuit comprises a circuit board 1100 and a mounting bracket 1102. The circuit board 1100 includes a safety detection switch 1104 and a trigger detection switch 1106. The safety detection switch 1104 comprises an electrical circuit configured to communicate electrical signals representative of changes in firing modes selected on the selective-fire weapon to a virtual reality computing device. The safety detection switch 1104 includes a safety detection switch button 1108 that toggles the safety detection switch 1104 and a switch lever interface 1110 that interfaces the safety detection switch button 1108 with a safety selector lever. The switch lever interface 1110 comprises a mechanical structure that is adapted to a safety selector lever, which is described in further detail with respect to the description of FIG. 13. Trigger detection switch 1106 comprises an electrical circuit configured to communicate electrical signals representative of trigger pull on the selective-fire weapon to the virtual reality computing device. Trigger detection switch 1106 is toggled by a trigger detection switch button 1112 which can be activated by trigger pull movement of the selective-fire weapon. Electrical signals communicated to the virtual reality computing device may be made via a wireless or wired connection.

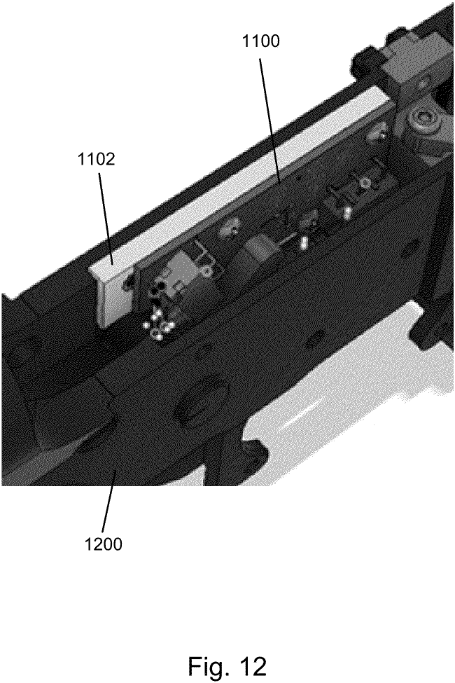

As illustrated in FIG. 12, the mounting bracket 1102 may be used to install the circuit board 1100 to a selective-fire weapon 1200, such as a M4 Carbine or other assault rifles. The circuit board 1100 is seated within a cavity at, for example, the lower receiver of selective-fire weapon 1200 and the mounting bracket 1102 secures the circuit board 1100 in place to detect toggling of a trigger (via trigger detection switch 1106) and a safety selector switch (via safety detection switch 1104) on the selective-fire weapon.

FIGS. 13 and 14 present cutaway views of an adapter circuit configured in a lower receiver according to an embodiment of the present invention. Circuit board 1100 is seated inside a lower receiver 1300 of a selective-fire weapon such that trigger detection switch button 1112 is operable by trigger mechanism 1302 and safety detection switch button 1108 is operable by safety selector lever 1304 via switch lever interface 1110. Trigger mechanism 1302 is position below trigger detection switch button 1112 and is configured to cause trigger detection switch button 1112 to toggle upon pulling or movement of the trigger mechanism 1302. Referring to FIG. 14, switch lever interface 1110 is coupled with safety selector lever 1304 such that safety detection switch button 1108 is toggled by switch lever interface 1110 by rotating the face of safety selector lever 1304.

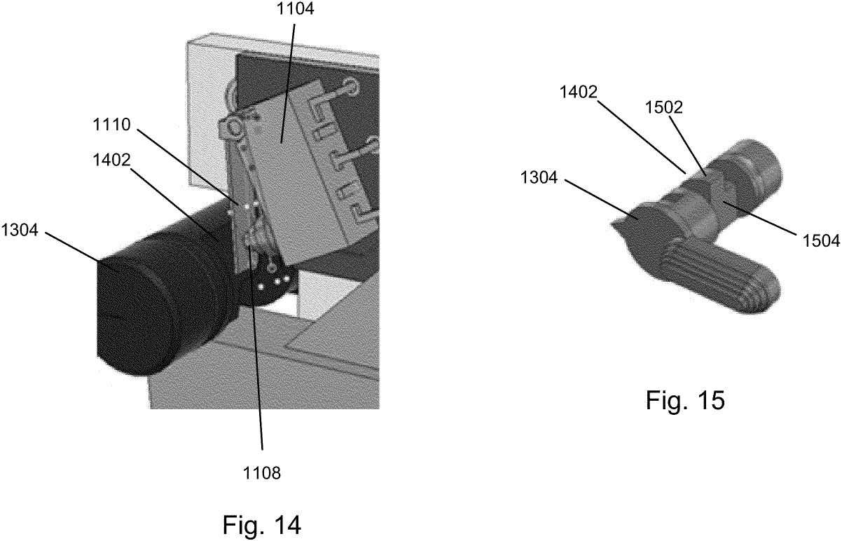

FIG. 15 presents an exemplary safety selector switch according to an embodiment of the present invention. The safety selector switch 1304 comprises a rotating mechanism with a plurality of positions (e.g., safety, semi-automatic, and automatic modes). Given that trigger mechanism 1302 is inoperable when the safety selector switch 1304 is on safety, safety detection switch 1104 is configured to determine whether safety selector switch 1304 is set to given firing modes (e.g., semi-automatic, burst, and automatic). Safety selector switch 1304 may include a channel 1402 having a notched portion 1502 and a cutout portion 1504. Switch lever interface 1110 is configured within channel 1402 such that rotating safety selector switch 1304 causes the switch lever interface 1110 to travel between the notched portion 1502 and the cutout portion 1504. As such, each of the notched portion 1502 and the cutout portion 1504 can be used to toggle between the firing modes.

FIGS. 1 through 15 are conceptual illustrations allowing for an explanation of the present invention. Notably, the figures and examples above are not meant to limit the scope of the present invention to a single embodiment, as other embodiments are possible by way of interchange of some or all of the described or illustrated elements. Moreover, where certain elements of the present invention can be partially or fully implemented using known components, only those portions of such known components that are necessary for an understanding of the present invention are described, and detailed descriptions of other portions of such known components are omitted so as not to obscure the invention. In the present specification, an embodiment showing a singular component should not necessarily be limited to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

It should be understood that various aspects of the embodiments of the present invention could be implemented in hardware, firmware, software, or combinations thereof. In such embodiments, the various components and/or steps would be implemented in hardware, firmware, and/or software to perform the functions of the present invention. That is, the same piece of hardware, firmware, or module of software could perform one or more of the illustrated blocks (e.g., components or steps). In software implementations, computer software (e.g., programs or other instructions) and/or data is stored on a machine-readable medium as part of a computer program product and is loaded into a computer system or other device or machine via a removable storage drive, hard drive, or communications interface. Computer programs (also called computer control logic or computer-readable program code) are stored in a main and/or secondary memory, and executed by one or more processors (controllers, or the like) to cause the one or more processors to perform the functions of the invention as described herein. In this document, the terms “machine readable medium,” “computer-readable medium,” “computer program medium,” and “computer usable medium” are used to generally refer to media such as a random access memory (RAM); a read only memory (ROM); a removable storage unit (e.g., a magnetic or optical disc, flash memory device, or the like); a hard disk; or the like.

The foregoing description of the specific embodiments will so fully reveal the general nature of the invention that others can, by applying knowledge within the skill of the relevant art(s) (including the contents of the documents cited and incorporated by reference herein), readily modify and/or adapt for various applications such specific embodiments, without undue experimentation, without departing from the general concept of the present invention. Such adaptations and modifications are therefore intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one skilled in the relevant art(s).

What is claimed is:

1. A circuit board for detecting selective fire of a selective-fire weapon coupled to a virtual reality system, the circuit board comprising:
a safety detection switch comprising a first electrical circuit configured to communicate signals representative of firing modes selected on a selective-fire weapon to a virtual reality computing device;
a trigger detection switch comprising a second electrical circuit configured to communicate signals representative of trigger pull on the selective-fire weapon to the virtual reality computing device; and
a mounting bracket configured to mount the circuit board to the selective-fire weapon.

2. The circuit board of claim 1 wherein the firing modes include at least one of safe, semi-automatic, burst, and fully automatic.

3. The circuit board of claim 1 wherein the switch lever interface comprises a mechanical structure adapted to the safety selector lever.

4. The circuit board of claim 1 wherein the firing mode signals and the trigger pull signals are communicated to the virtual reality computing device via a wireless or wired connection.

5. The circuit board of claim 1 wherein the selective-fire weapon comprises a M4 Carbine.

6. The circuit board of claim 1 wherein the mounting bracket is configured to mount the circuit board within a cavity of the selective-fire weapon.

7. The circuit board of claim 1 wherein the mounting bracket is configured to mount the circuit board to a lower receiver of the selective-fire weapon.

8. The circuit board of claim 1 wherein the trigger detection switch button is toggled by trigger pull movement of a trigger mechanism of the selective-fire weapon.

9. The circuit board of claim 1 wherein the safety detection switch button is toggled via the switch lever interface by rotating a face of the safety selector lever.

10. The circuit board of claim 1 wherein the safety selector switch comprises a rotating mechanism including a plurality of positions corresponding to the firing modes.

11. The circuit board of claim 1 wherein the safety selector switch includes a channel having a notched portion and a cutout portion, the notched portion and the cutout portion corresponding to positions associated with the firing modes.

12. The circuit board of claim 11 wherein the switch lever interface is configured within the channel.

13. The circuit board of claim 12 wherein rotating safety selector switch toggles between the firing modes by causing the switch lever interface to travel between the notched portion and the cutout portion.

14. The circuit board of claim 1 wherein the safety detection switch includes a safety detection switch button that toggles the safety detection switch and a switch lever interface that interfaces the safety detection switch button with a safety selector lever.

15. The circuit board of claim 1 wherein the trigger detection switch includes a trigger detection switch button that toggles the trigger detection switch by trigger pull movement of the selective-fire weapon.
